(19) United States
(12) Patent Application Publication
(10) Pub. No.: US 2013/0076450 A1
(43) Pub. Date: Mar. 28, 2013

(54) LOW NOISE BIAS CIRCUIT FOR A PLL OSCILLATOR

(71) Applicants: Chethan Rao, San Jose, CA (US); Shaishav Desai, San Jose, CA (US); Alvin Wang, Saratoga, CA (US)

(72) Inventors: Chethan Rao, San Jose, CA (US); Shaishav Desai, San Jose, CA (US); Alvin Wang, Saratoga, CA (US)

(73) Assignee: MOSYS, INC., Santa Clara, CA (US)

(21) Appl. No.: 13/244,254

(22) Filed: Sep. 23, 2011

(51) Int. Cl. H03L 7/08

(52) U.S. Cl. 331/34

(57) ABSTRACT

A system, method, and apparatus for generating a low noise bias current to improve jitter performance in a wide frequency range LC-based phase-locked loop (PLL) circuit for multi-speed clocking applications. A plurality of noise-reducing stages are coupled in series and disposed between a power supply and a voltage controlled oscillator (VCO) including: a first stage VCO regulator; and a second stage bias circuit having a plurality of PMOS transistors cascode-coupled to each other and optionally grouped into one or more parallel branches of cascode-coupled transistor pairs. Each branch can be automatically enabled by a calibration code based on the desired reference clock signal in order to provide a wide range of currents to the voltage controlled oscillator. The cascode coupled pair includes a bias transistor coupled in series with a self-biased current buffer to provide high output impedance with minimal current change for any input voltage change from noise.

### CROSS-REFERENCE TO RELATED APPLICATIONS

This application claims priority to application(s): Ser. No. 12/430,430 filed Apr. 27, 2009, entitled “LOW JITTER LARGE FREQUENCY TUNING LC PLL FOR MULTI-SPEED CLOCKING APPLICATIONS;” Provisional Application Ser. No. 61/192,847 entitled “A Low Jitter Large Frequency Tuning LC PLL in CMOS for Multi-GHz Clocking Applications” filed Sep. 22, 2008; which application(s) are also incorporated by reference herein in their entirety.

### FIELD OF TECHNOLOGY

This disclosure relates generally to the technical fields of a bias circuit and more specifically to improving bias current integrity in a phase-locked loop (PLL) oscillator.

### BACKGROUND

A phase-locked loop is a well-known circuit that is typically used as a control system to generate a signal having a fixed relation to the phase of a reference signal. With reference to FIG. 1, a typical phase-locked loop is shown. The phase-locked loop 100 includes a phase detector 102, a voltage controlled oscillator (VCO) 104, and a feedback 106 path from the VCO 104 to the phase detector 102. The phase detector 102 receives as inputs a reference signal and a feedback signal from the VCO 104. The phase detector output controls the VCO 104 such that the phase difference between the two inputs is held constant. The VCO 104 generates an output frequency based on the output of the phase detector. Voltage controlled oscillators 104 are an integral part of high-speed serial interfaces, and the performance of the VCO 104 to a large extent can determine the performance of the PLL 100 as a whole.

With the ever-increasing data rates and density of high-speed serial interfaces in transmission systems, current Serializer-Deserializer (SerDes) transceivers need to be multi-data rate compatible to support new link speeds and standards while still being compatible with previous speeds and standards. Achieving the desirable higher data rates with older lossy and discontinuous channels places a large burden on silicon, particularly in equalization and clocking. As a consequence, it is desirable to have a low jitter phase-locked loop (PLL) that provides a tolerance in the transmit path jitter budget and also facilitates reliable data recovery by the clock and data recovery (CDR) delay-locked loop (DLL) and phase interpolator (PI) in the receiver.

Typically, when circuit designers attempt to satisfy the requirements of multiple standards with one PLL design, they use a ring-oscillator PLL. The inherent properties of ring-oscillator PLLs give them wide-bandwidth capabilities. However, ring-oscillator PLLs also traditionally suffer from poor jitter performance. Compared to the ring-oscillator PLLs, LC VCO based PLLs generally have superior jitter performance but a smaller VCO frequency range. It would be desirable to have a PLL solution with the jitter performance of a LC VCO based PLL and the wide-band performance of a ring-oscillator PLL.

### SUMMARY

The following is a simplified summary of one or more aspects of the present disclosure in order to provide a basic understanding of the present disclosure. This summary is not an extensive overview of all contemplated aspects, and is not intended to identify all the key or critical elements of all aspects of the present disclosure or to delineate the scope of any or all aspects of the present disclosure. Its sole purpose is to present some concepts of one or more aspects of the present disclosure in a simplified form as a prelude to the more detailed description that is presented later.

A system, method, and apparatus for generating a low noise bias current to improve jitter performance in a wide frequency range LC VCO based phase-locked loop (PLL) circuit for multi-speed clocking applications. The apparatus and system include a plurality of noise-reducing stages are coupled in series and disposed between a power supply and a voltage controlled oscillator (VCO) including: a first stage VCO regulator; and a second stage bias circuit having a plurality of PMOS transistors cascode-coupled to each other and optionally grouped into one or more parallel branches of cascode-coupled transistor pairs. Each branch can be automatically enabled by a calibration code to provide any combination of branches based on the desired reference clock signal in order to provide a wide range of currents to the voltage controlled oscillator. The cascode coupled pair includes a bias transistor coupled in series with a self-biased current buffer to provide high output impedance with minimal current change for any input voltage change from noise. An auto-calibration circuit generates the calibration code in response to the reference clock signal and the feedback clock signal, wherein the calibration code activates a set of calibration capacitors in the LC tank circuit and also adjusts the bias current generated in the bias circuit.

The method of generating a low noise bias current to improve jitter performance in a wide frequency range LC VCO based phase-locked loop (PLL) circuit for multi-speed clocking applications includes the following operations. A feedback clock signal is generated in response to a reference clock signal using an LC tank circuit having a plurality of calibration capacitors. The feedback clock signal and the reference clock signal are compared and, in response, a calibration code is generated that activates a set of the calibration capacitors to lock the PLL. A regulated supply voltage is generated and provided to a VCO regulator. Then residual noise from the VCO regulator is filtered via a plurality of transistors cascode-coupled to each other in a bias circuit, with low-noise generation characteristics, that is disposed between the VCO regulator terminal and the LC tank circuit. One or more sets of the parallely arranged cascode-coupled transistor pairs are enabled in response to the configuration code, thereby providing a bias current to the LC tank circuit. Initially all calibration capacitors in the LC tank circuit are activated, with one or more calibration capacitors of the LC tank circuit being de-activating if the reference clock signal has a higher frequency than the feedback clock signal, with a commensurate decrease in the bias current when one of the calibration capacitors is de-activated. The bias current is selected to maximize amplitude of an output signal provided by the LC tank circuit, without causing the LC tank circuit to operate in a voltage-limited region. The generation of the calibration code occurs at approximately the same time, and in one case simultaneously, to configure both the calibration capacitors and the cascode-coupled transistors in the bias circuit.

To accomplish the foregoing and related ends, the one or more aspects of the present disclosure comprise the features hereinafter that are fully described particularly pointed out, and distinctly claimed. The following description and the annexed drawings set forth in detail, certain illustrative features of the one or more aspects of the present disclosure. These features are indicative, however, of but a few of the various ways in which the principles of present disclosure may be employed, and this description is intended to include all the aspects of the present disclosure and their equivalents. Other features will be apparent from the accompanying drawings and from the detailed description that follows. Accordingly, the specification and drawings are to be regarded in an illustrative rather than a restrictive sense.

### BRIEF DESCRIPTION OF THE VIEW OF DRAWINGS

Example embodiments are illustrated by way of example and not limitation in the figures of the accompanying drawings, in which like references indicate similar elements and in which:

FIG. 1 illustrates a general component block diagram of a phase-locked loop, in accordance with one or more embodiments.

FIG. 2 is a general component block diagram of a low-jitter large frequency tuning LC VCO based phase-locked loop circuit in accordance with one or more embodiments.

FIG. 3A is a schematic of a differential LC tank circuit with a plurality of noise-reducing stages and a fixed VCO bias current source circuit, in accordance with one or more embodiments.

FIG. 3B is a schematic of a differential LC tank circuit with a plurality of noise-reducing stages and an adjustable VCO bias circuit, in accordance with one or more embodiments.

FIG. 4 illustrates an example layout of the phase-locked loop in accordance with an aspect of the subject specification;

FIG. 5 illustrates an example circuit diagram of a programmable charge pump architecture in accordance with an aspect of the subject specification;

FIG. 6A is an example circuit diagram illustrating the architecture of an individual charge pump with a second order loop filter in accordance with an aspect of the subject specification;

FIG. 6B is an example circuit diagram illustrating the architecture of an individual charge pump with a third-order loop filter incorporating a low pass filter accordance with an aspect of the subject specification;

FIG. 7 illustrates an example design of a passive loop filter in accordance with an aspect of the subject specification;

FIG. 8 illustrates an example detailed circuit diagram of a programmable VCO architecture in accordance with an aspect of the subject innovation;

FIG. 9 illustrates an example coarse calibration circuit unit cell in accordance with an aspect of the subject specification;

FIG. 10 illustrates an example circuit diagram of an auto-calibration circuit in accordance with an aspect of the subject specification;

FIG. 11 illustrates an example circuit diagram of a calibration select circuit in accordance with an aspect of the subject specification;

FIG. 12 illustrates an example top level diagram of a feedback clock divider in accordance with an aspect of the subject specification;

FIG. 13 illustrates an example top level diagram of a per lane clock divider in accordance with an aspect of the subject specification;

FIG. 14 is an example graphical representation of the VCO frequency vs. calibration code measurements in accordance with an aspect of the subject specification;

FIG. 15 is an example graphical representation of the measured closed loop frequency spectrum of the phase-locked loop in accordance with the subject specification;

FIG. 16 is an example graphical representation of a set of jitter measurements of the phase-locked loop in accordance with an aspect of the subject specification;

FIG. 17 is an example graphical representation of a jitter plot in accordance with an aspect of the subject specification;

FIG. 18 is an example graphical representation of a plot of the transmission eye in accordance with an aspect of the subject specification;

FIG. 19 is an example graphical representation of a plot of the transmission jitter in accordance with an aspect of the subject specification; and

FIG. 20 illustrates a silicon die micrograph for a LC VCO based PLL embedded in a 4-lane macro. Other features of the present embodiments will be apparent from the accompanying drawings and from the detailed description that follows.

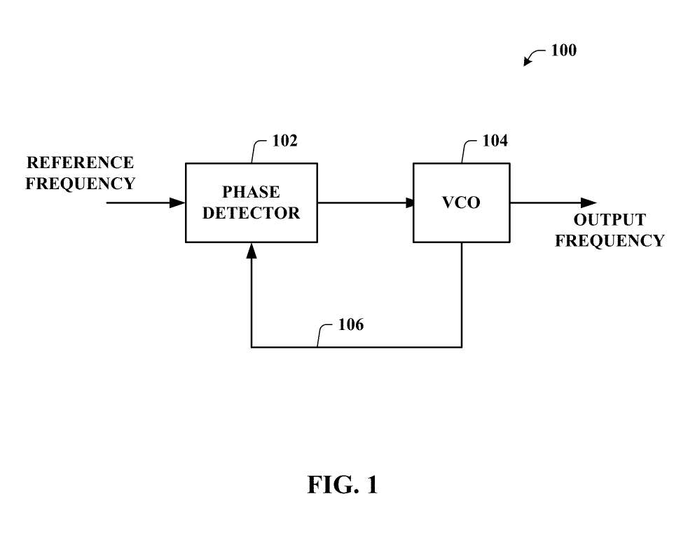

### DETAILED DESCRIPTION

The innovation is now described with reference to the drawings, wherein like reference numerals are used to refer to like elements throughout. In the following description, for purposes of explanation, numerous specific details are set forth in order to provide a thorough understanding of the subject innovation. It may be evident, however, that the innovation can be practiced without these specific details. In other instances, well-known structures and devices are shown in block diagram form in order to facilitate describing the innovation.

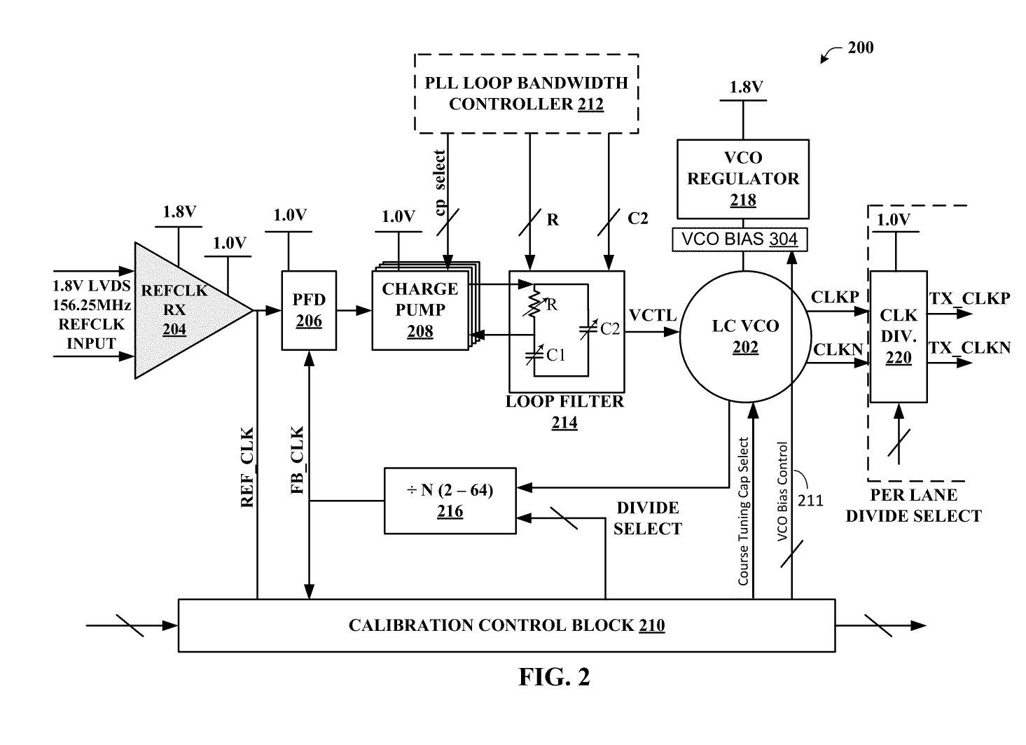

FIG. 2 is an example functional block diagram of a low-jitter large frequency tuning LC VCO based phase-locked loop circuit that can be used for multi-speed clocking applications in accordance with an aspect of the present innovation. The phase-locked loop (PLL) 200 provides an output frequency that can be used for a plurality of applications. The PLL can be used to generate stable frequencies, recover a signal from a noisy communication channel, or distribute clock timing pulses in digital logic circuits. A voltage-controlled oscillator (VCO) 202 is central to the design of a PLL 200, because the VCO 202, to a large extent, determines the performance of the PLL 200 (discussed below). An approach of the present disclosure is to use a traditional second order passive loop filter 214 and a charge pump 208 combined with sufficient digital control circuitry to make the PLL 200 programmable and adaptable to satisfy a plurality of loop bandwidth (LBW) and peaking requirements.

Beginning on the left side of FIG. 2, a reference clock receiver (e.g., Refclk Rx) 204 obtains, acquires, or otherwise receives a reference clock signal. The reference clock receiver 204 can be, for example, a 1.8V low-voltage differential signaling (LVDS) reference clock receiver having a maximum operating frequency of 5.2 GHz. The reference clock signal can have a frequency of, for example, 156.25 MHz. The reference clock receiver supplies an input signal to a phase frequency detector (PFD) 206 based on the frequency of the reference clock input. In addition, the PFD 206 receives a feedback signal (e.g., FB_CLK) from the LC VCO 202. The PFD 206 compares the frequencies of the input signal and the feedback signal, and produces an error signal proportional to the difference of the two signals.

The error signal is provided to a programmable charge pump 208. The charge pump 208 is an electronic circuit that uses capacitors as energy storage elements to create an adjustable voltage power source. The charge pump 208 is programmable because it can contain a plurality of individual charge pumps, and the number of charge pumps that are active at a given time can be determined, selected, or otherwise programmed, e.g., via cp_select signal from PLL loop bandwidth controller 212. For example, the charge pump 208 can contain four individual charge pumps, wherein a designer can activate a desired number of the charge pumps (e.g., one to four) via an external PLL loop bandwidth controller 212, which can be implemented in hardware, software or firmware. The controller 212 can be implemented as a portion of the calibration control block 210 module or can be a separate module.

The charge pump 208 supplies an output voltage signal to a loop filter 214. The loop filter 214 removes unwanted high frequency components from the voltage signal that are not removed by the phase frequency detector 206 so that they are not transmitted to the VCO input line (i.e. tune line). Loop filters are generally constructed by using operational amplifiers (op-amps). A disadvantage of the op-amps is that they can inject additional noise into the PLL 200. In the preferred embodiment of present disclosure, the loop filter 214 is constructed of passive elements to reduce the overall noise.

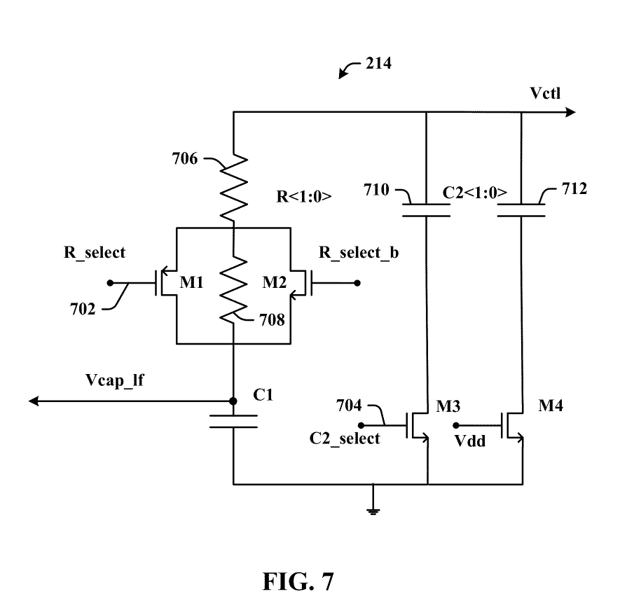

As illustrated in FIG. 2, there is a feedback loop between the charge pump 208 and the loop filter 214. This feedback loop functions to reduce the deterministic jitter (DJ) and thus further decreases the overall noise in the PLL 200. The loop filter 214 is programmable via a set of resistors, R, and a set of capacitors, C2, wherein the designer can select the number of active resistors R and capacitors C2 via the controller 212 (see FIG. 7). The programmability of the charge pump 208 and RC loop filter 214 enables tweaking of the PLL's 200 bandwidth properties. By programming the charge pump 208 and loop filter 214 independently, the designer can program the PLL 200 bandwidth. For example, the programmability incorporated in the charge pump 208 and loop filter 214 allows the PLL 200 to achieve a loop bandwidth (LBW) operating range of 1.6 to 9 MHz across the LC VCO 202 frequency range. Loop bandwidth (LBW) is an important performance parameter of a PLL circuit. Generally, a higher LBW is preferable to a lower LBW because the higher LBW enables the PLL to better track the reference frequency. However, conventional PLLs with high LBW cannot reliably block the jitter caused by the reference frequency, which is undesirable. The present disclosure provides a PLL with a high LBW and a superior jitter performance.

The loop filter 214 outputs a control voltage VCTL signal, which serves as the input voltage for the LC VCO 202. The LC VCO 202 produces an output signal (CLKP or CLKN) having a frequency based on the control voltage signal VCTL obtained from loop filter 214. The output signal is also supplied to the feedback loop having a feedback divider 216. The feedback divider 216 can divide the frequency of the feedback signal received from the LC VCO 202 by N and provide the signal having the new frequency (FB_CLK) to the PFD block 208, where N can be an integer ranging from, for example, two (2) to sixty four (64) in increments of one (1). The purpose of the division is to enable the PFD 206 to compare the FB_CLK signal with the reference frequency signal provided by the reference frequency clock receiver 204. For example, if signal provided by the reference frequency clock receiver has a frequency of 156.25 MHz and the signal output by the LC VCO 202 has a frequency of 5 GHz, the feedback driver 216 can divide frequency of the LC VCO 202 output signal by 32 and provide the new signal having a frequency of 156.25 MHz (FB_CLK) to the PFD 206. The calibration control block 210 can be programmed to determine the value of N and provide that value N to the feedback divider 216 by way of the DIVIDE/SELECT channel.

The LC VCO 202 receives a high supply voltage of V_{DD-HV}, e.g., 1.8V, from an external power supply. Typically, power supplies can be a significant source of noise in electronic circuits, which can be particularly disruptive to the performance of the LC VCO 202. A VCO regulator 218 is provided to mitigate the effects of supply noise from the 1.8V supply. In the preferred embodiment of the present disclosure, the PLL 200 has a VCO frequency range of 2.1875 GHz to 5 GHz using a 156.25 MHz reference clock.

The PLL 200 can also include a programmable clock divider 220 at the transmission (Tx) input of each lane (e.g., TX_CLKP, TX_CLKN), wherein the clock divider 220 can divide the frequency by an integer M, where M includes 1, 2, 4, or 8 (discussed below). The clock divider 220 enables the designer to further extend the PLL frequency range from 273.4375 MHz (2.1875 GHz/8) to 5 GHz. The value of the integer M can be selected by the calibration control block 210 and provided to the clock divider 220 by way of the PER LANE DIVIDE SELECT channel. One of ordinary skill in the art can appreciate that the clock dividers 220 for the various lanes can use different values of the integer M such that each lane can transmit a clock signal having a difference frequency from the other lanes. Many blocks in FIG. 2, e.g., 206, 208, 220, are powered by an analog supply voltage, V_{DD-A}, e.g., 1.0V, which is lower than V_{DD-HV}. A wide range of supply voltages can be utilized in the present disclosure.

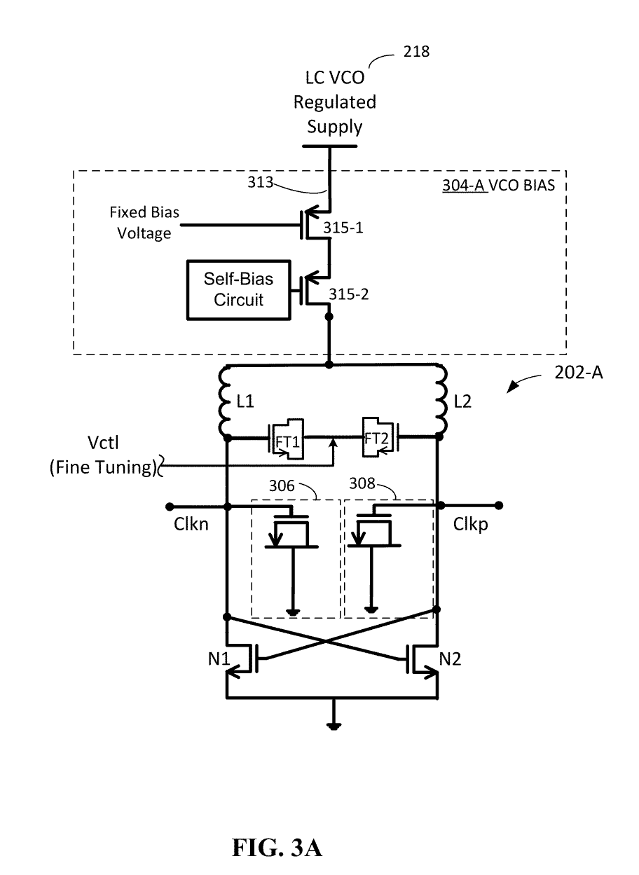

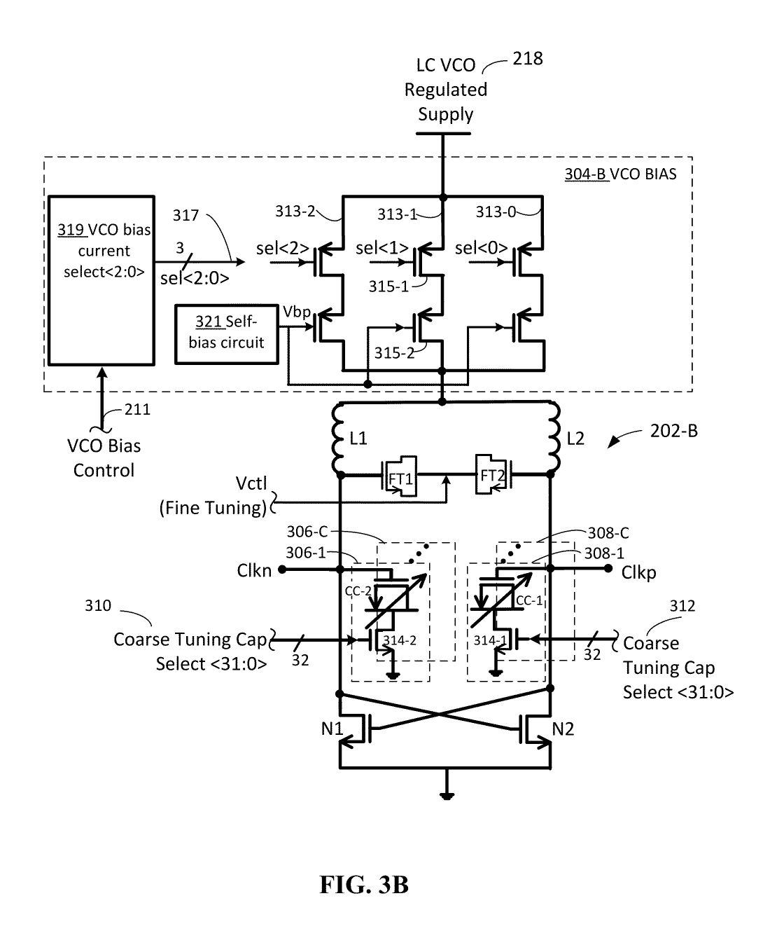

Turning now to FIG. 3A, a schematic of a differential LC tank circuit 202 with a plurality of noise-reducing stages and a fixed VCO bias current source circuit 304-A is shown, in accordance with one or more embodiments. The plurality of noise-reducing stages includes a VCO regulator 218 that acts as a first stage in reducing noise from voltage supply, e.g., 1.8 V supply shown in FIG. 2, and a fixed VCO bias 304-A circuit that acts as a second stage, both of which are coupled in series and disposed between the voltage supply and the differential LC tank circuit 202.

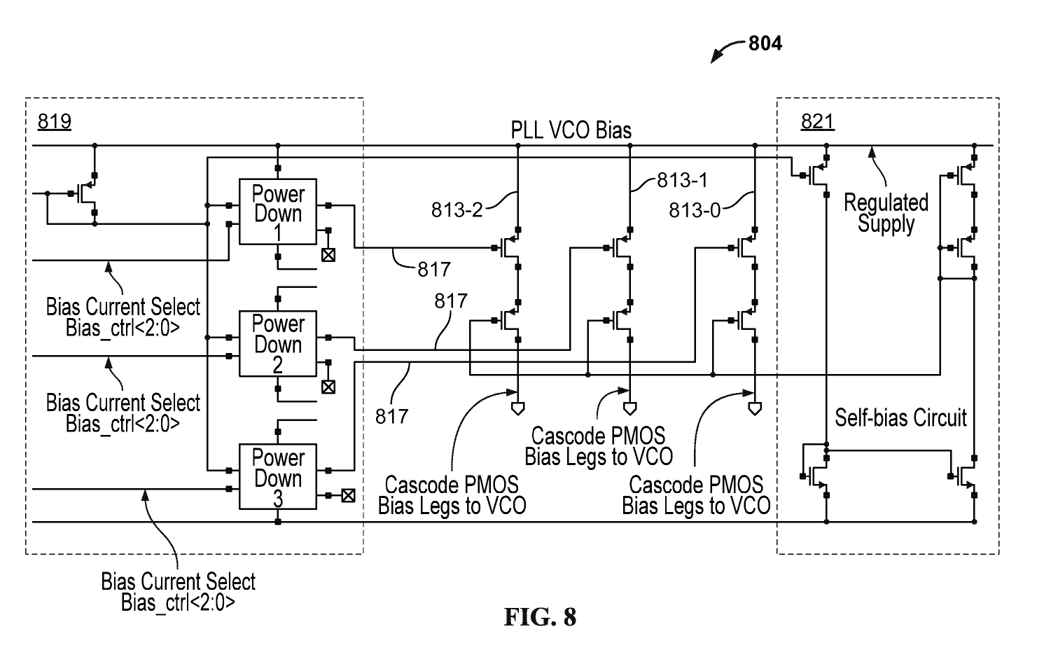

The second stage reduces noise from VCO regulator 218 in two ways. First, PMOS type transistors are used in the current source 304 for the VCO 202 because the PMOS transistors have lower inverse frequency (1/f) noise than a NMOS source for a given bias current, and therefore has lower noise generation properties, e.g., less flicker noise. Second, multiple PMOS transistors, e.g., a pair of transistors, are cascode-coupled, e.g., 315-1 and 315-2, into a current source, as shown in FIG. 3 as well as in FIG. 8, to further reduce noise, as compared to a single PMOS transistor current source. In particular, a bias transistor, e.g., PMOS 315-1, is coupled in series with a self-biased current buffer, e.g., PMOS 315-2 as a baseline of a single cascode-coupled branch that provides high output impedance for the pair, and thus a minimal current change for any input voltage change from noise. First transistor 315-1 gate is coupled to a fixed bias voltage from a global bias reference, while second transistor 315-2 is coupled to a self-bias circuit, shown in more detail in subsequent FIG. 8. Together, the serially coupled PMOS transistors sequentially, cumulatively, and significantly reduce noise in the current supply provided to the LC tank circuit 202.

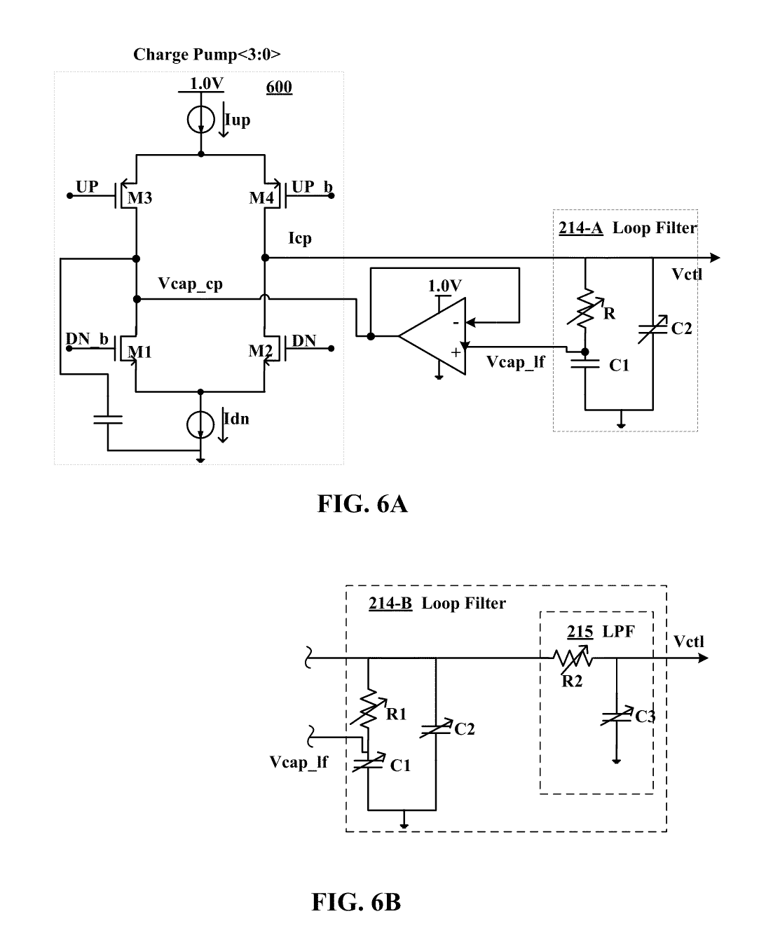

The VCO bias 304-A is shown coupled to the LC tank (e.g., LC VCO) 202-A. The LC tank 202-A uses 1.8V NMOS in Nwell accumulation-mode varactors (e.g., FT1 and FT2) and high-Q spiral inductors (e.g., L1 and L2). The Vctl (e.g., fine-tuning) obtained from the loop filter discussed below with respect to FIG. 6 controls the varactors FT1 and FT2. In order to improve substrate noise rejection double guard rings are used on the varactors FT1 and FT2 and NMOS switching transistors (e.g., N1 and N2) are used as switches. The LC tank 202-A is fixed with a first and second calibration circuits 306 and 308.

By providing a very low-noise current to the LC tank circuit 202-A, the jitter of a resonant frequency generated in the LC VCO 202-A is substantially reduced. However, the effective frequency range of the LC tank circuit 202-A is limited to the range of current provided by the single cascode-coupled branch 313 in VCO bias circuit 304-A.

Referring now to FIG. 3B, a schematic of a differential LC tank circuit 202 with a plurality of noise-reducing stages and an adjustable VCO bias circuit 304-B is shown, in accordance with one or more embodiments. The plurality of noise-reducing stages are serially coupled to each other and disposed between the external power supply, e.g., the 1.8V source, and the LC VCO 202 in order to sequentially, cumulatively, and significantly reduce noise in the current supply provided to the LC tank circuit 202 over a wider frequency range than a fixed VCO bias circuit. Similar to FIG. 3A, VCO regulator 218 (e.g., regulated supply) acts as a first stage to isolate supply noise from leaking into the VCO 202.

To provide configurability, FIG. 3B has a programmable VCO bias current source 304-B for a second stage that further mitigates, or filters, the effects of supply noise that pass through VCO regulator 218, and thereby further reduces noise from entering LC tank circuit 202. The plurality of transistors in VCO bias current source 304 are grouped into a plurality of sets, or branches, 313-0, 313-1, and 313-2 in FIG. 3B of similarly cascode-coupled PMOS transistors, e.g., transistor pairs, are arranged and coupled in parallel to provide a wide range of possible currents to LC VCO 202-B to commensurately enable a wide range of possible resonant frequencies in the LC VCO 202-B. Each of branches 313-0, 313-1, and 313-2 can have similar current ratings for a multiplier effect, e.g., 1, 2 or 3 times the current depending on the quantity of branches utilized. Alternatively, each of the branches can have different resolutions of current ratings to allow more granularity and more combinations that are possible. For example, in the latter case, the branches can have current rating of M, 0.5M, and 0.25M, where M is any target value of current, and thereby provide seven possible non-zero unique combinations of current from one to three branches, resulting in a current range of 0.25M to 1.75M. The desired bias current is realized by selectively enabling, or coupling in parallel, one or more branches 313-0, 313-1, and 313-2, e.g., via an automatically generated VCO_BIAS_CTRL signal 211 from calibration control block 210 of FIG. 2, to VCO bias current select block in FIG. 3B, thereby providing the appropriate bias current to the appropriate desired branch(es) based on the user-input desired reference clock, and feedback divider 216 value of N which will then provide the desired current to the voltage controlled oscillator 202-B.

For example, at a high end of the frequency range of PLL 200, e.g., 5 GHz, a smaller quantity of current is needed for LC tank circuit 202-B, per design simulations, and thus, VCO bias current select block and calibration control block 210 are encoded to send/receive a VCO bias control signal 211 that will enable only an appropriate portion of the plurality of sets of cascode-coupled PMOS transistors, 313-0, 313-1 or 313-2 to provide the precise current that allows the LC tank to operate with minimum jitter at the desired frequency. In the high frequency range case, one embodiment only utilizes a single set of cascode-coupled PMOS transistors, e.g., 313-0.

Similarly, in another example at a low end of the frequency range of PLL 200, e.g., 2.343 GHz, a larger quantity of current is needed for LC tank circuit 202-B, per design simulations, and thus, VCO bias current select block and calibration control block 210 are encoded similarly to send/receive a VCO bias control signal 211 that will enable a larger quantity of current to be provided through the appropriate selection of the plurality of sets of cascode-coupled PMOS transistors, 313-0, 313-1 or 313-2 to provide the precise current that allows the LC tank to operate with minimum jitter at the desired frequency. In this low frequency range case, one embodiment utilizes the entire plurality of sets of cascode-coupled PMOS transistors, e.g., 313-0, 313-1, and 313-2. A similar example with a frequency between the minimum and maximum operating frequency range would operate a quantity of the plurality of sets of cascode-coupled PMOS transistors between one set and all the sets. The self-biased circuit block and VCO bias current select block are shown in more detail in subsequent FIG. 8.

The VCO bias 304-B is shown coupled to the LC tank (e.g., LC VCO) 202-B. The LC tank 202-B is designed to have a relatively low average sensitivity (KVCO) of approximately 600 MHz/V to minimize the deterministic jitter and varactor amplitude modulation to phase modulation (AM-to-PM) conversion caused due to the low frequency bias noise. The LC tank 202 uses 1.8V NMOS in Nwell accumulation-mode varactors (e.g., FT1 and FT2) and high-Q spiral inductors (e.g., L1 and L2). The Vctl (e.g., fine-tuning) obtained from the loop filter discussed below with respect to FIG. 6 controls the varactors FT1 and FT2. In order to improve substrate noise rejection double guard rings are used on the varactors FT1 and FT2 and NMOS switching transistors (e.g., N1 and N2) are used as switches.

The LC tank 202 further includes a first coarse tuning calibration circuit 306-1 through 306-C and a second coarse tuning calibration circuit 308-1 through 308-C, where C is 32. The coarse tuning calibration circuits 306-1 through 306-C and 308-1 through 308-C each include a first coarse tuning cap select 310 and a second coarse tuning cap select 312, respectively. The coarse tuning cap select can activate one or more of 32 capacitors (e.g., CC<0:31>) on either side of the differential pair, e.g., CC-1, CC-2 by opening or closing the coarse tuning transistors, e.g., 314-1 and 314-2, respectively

As discussed previously, the coarse tuning cap select can be controlled by the calibration logic (e.g., calibration control block 210). As the calibration logic alters the number of active capacitors, e.g., by activating or de-activating capacitors, it also adjusts the current via the VCO bias 304. For example, the current can be adjusted within the range of 3 mA to 10 mA. The control logic is preprogrammed to adjust the VCO bias 304 for low noise at each desired frequency. Calibration control block 210 can generate calibration codes to configure both the first coarse tuning calibration circuit 306-1 through 306-C and the second coarse tuning calibration circuit 308-1 through 308-C, as well as calibrate the VCO bias current select block at approximately the same time, and in one embodiment it is done simultaneously, for a fast and efficient initialization and lock of the PLL circuit 200 for a desired frequency within the wide range of operating frequencies of the PLL 200, e.g., from 2.1875 GHz to 5 GHz.

While FIG. 3A provides a baseline configuration VCO bias circuit 304-A coupled to a baseline LC based VCO 202-A, and while FIG. 3B provides a fully programmable VCO bias circuit 304-B coupled to a fully programmable LC based VCO 202-B, the present disclosure is well suited to different combinations of both FIGS. 3A and 3B. For example, a fully programmable VCO bias circuit 304-B can be coupled with a baseline configuration LC VCO 202-A in another embodiment, or a baseline VCO bias circuit 304-A can be coupled with a fully programmable LC VCO 202-B in yet another embodiment, in order to provide tailored solutions for different applications.

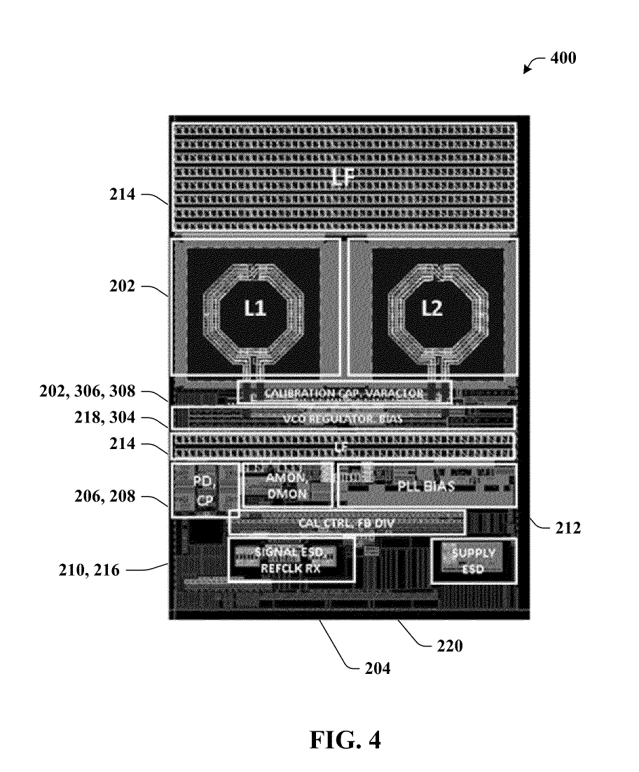

In view of the example systems described supra, the disclosed subject matter will be better appreciated with reference to FIGS. 4-13 illustrating an embodiment of the innovation as actually fabricated by the inventors thereof. The figures illustrate various parts and components of the previously disclosed system in detail. However, it is to be appreciated that this is but one embodiment and those skilled in the art may be able to readily identify equivalent embodiments within the scope and spirit of the current specification. Furthermore, the innovation described herein can additionally, or alternatively, be constructed using hardware, software, field programmable gate arrays (FPGA), and so forth.

In an embodiment of present disclosure fabricated by the inventors, using a 156.25 MHz clock, the PLL lock was verified at 2.343 GHz, 2.5 GHz, . . . , 4.843 GHz and 5 GHz (i.e. at f.sub.vco=156.25 MHz*X, where X=15, 16, . . . , 31, 32). The RMS random jitter (RJ.sub.rms) of the PLL was measured to be 460 fs at 5 GHz (10 Gb/s), 548 fs at 3.125 GHz and less than 750 fs across the entire VCO frequency range while the total power consumed from the 1.8V and 1.0V power supply was of the order of 32 mW. Moreover, using the figure of merit (FOM): {(f.sub.vco,max-f.sub.vco,min)/f.sub.vco,avg}*100}, the LC VCO was found to have a coarse tuning range of 66% and a worst-case hold range (fine tuning range at minimum VCO frequency) of 9.6%. These findings are illustrated by Table 1 below:

TABLE-US-00001
Table of Measured Performance

| | |
|---|---|
| Technology | 65 nm CMOS 10-metal copper/low-k |
| Supply Voltage | 1.0 V (core), 1.8 V (I/O) |
| Input Reference Clock | 156.25 MHz |
| VCO Frequency Range | |
| Coarse Calibration Range | 2.3 to 4.6 GHz, or 66% |
| Fine tuning range | 9.6% (minimum), 17.3% (maximum) |
| Total tuning range | 2.1875 to 5 GHz |
| Phase Noise at 1 MHz offset | |
| Closed Loop Phase Noise: 3.125 | −117.18 dBc/Hz |
| GHz | |
| Closed Loop Phase Noise: 5 | −109.31 dBc/Hz |
| GHz | |
| Output Jitter | |
| RJ.sub.rms: 3.125 Ghz | 548 fs |
| RJ.sub.rms: 5 GHz | 460 fs |
| Loop Bandwidth | |
| Programmable Range | 1.6 to 9 MHz |
| Peaking | 1.6 dB maximum |
| Feedback Divider | 2 to 64 in increments of 1 |
| Silicon Area | 0.35 mm² (500 um × 700 um) |
| Power | 32 mW at 5 GHz (1.0 V, 1.8 V, 25° C.) |

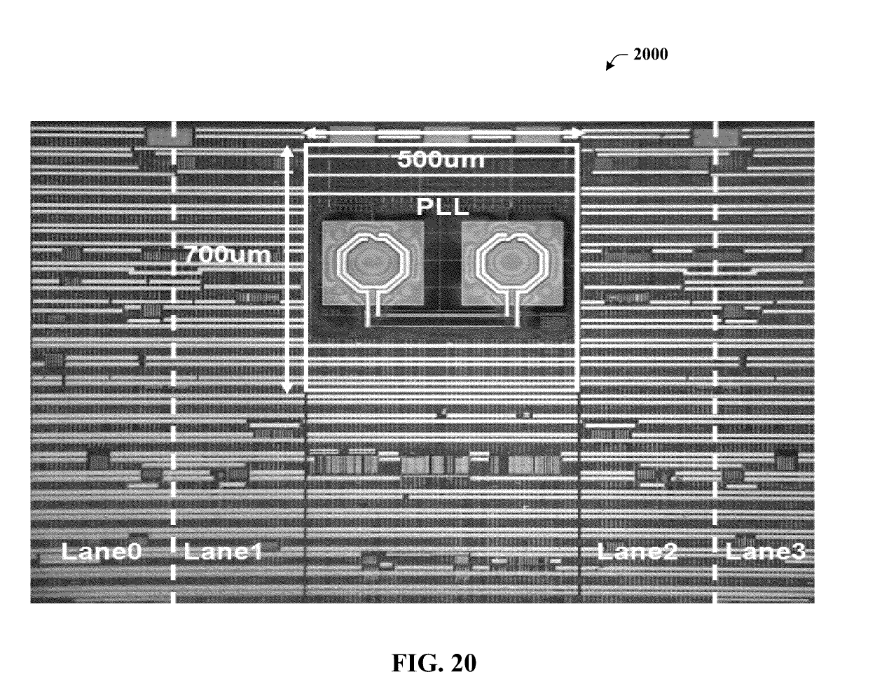

FIG. 4 illustrates a silicon layout 400 of an actual embodiment of the phase-locked loop 200 in accordance with an aspect of the subject innovation. Detailed circuit diagrams for the various components of the PLL 200 shown in FIG. 4, including the programmable charge pumps 208, passive loop filter 214, programmable VCO architecture 202, feedback divider 216, per lane clock divider 220, and their sub components are provided below. One of ordinary skill will appreciate that the clock divider 220 illustrated in FIG. 4 can be implemented either on or off the silicon 400. One of ordinary skill in the art will also appreciate that the PLL 200 can include multiple clock dividers 220. FIG. 20 illustrates a silicon die micrograph 2000 for a LC VCO based PLL embedded in a 4-lane (lane 0-3) Serializer/Deserializer (SerDes) macro.

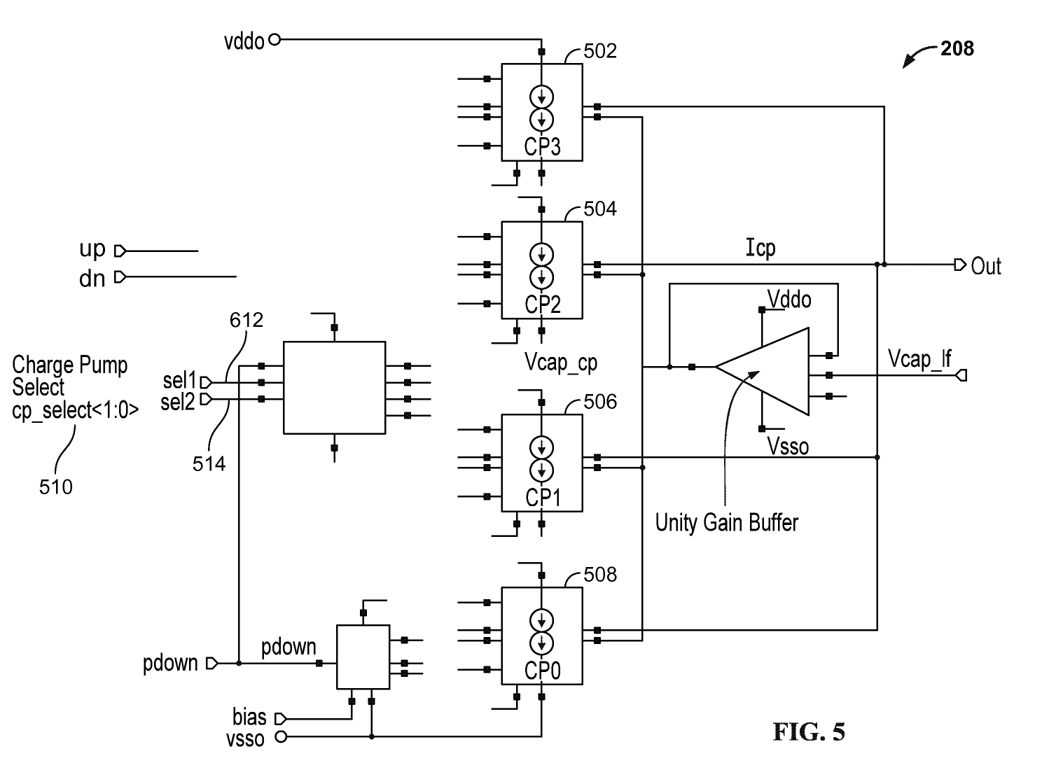

FIG. 5 illustrates an example circuit diagram of a programmable charge pump 208 architecture in accordance with an aspect of the subject innovation. The charge pump 208 includes a first charge pump 502, a second charge pump 504, a third charge pump 506, and a fourth charge pump 508. The charge pumps 502-508 can be activated via a charge pump select 510 (e.g., cp_select<1:0>). The charge pump select 510 includes a first select line 512 (e.g., sel1), and second select line 514 (e.g., sel2). By setting the select lines 512 and/or 514 to a binary zero (0) or one (1) a designer can activate one or more of the charge pumps 502-508. For example, setting the first select line 512 to zero (0) and the second select line 514 to zero (0) can activate the first charge pump 502.

FIG. 6A illustrates an example circuit diagram illustrating the architecture of an individual charge pump (CP) coupled to a second order loop filter (LF) 214-A in accordance with an aspect of the present innovation. For example, the charge pump 600 can be illustrative of the architecture for any of the charge pumps 502-508 (see FIG. 5). The CP current Icp is programmable and nominally ranges from 0.25 to 1 mA. The programmable resistance R and ripple capacitance C2 in the LF 214-A along with Icp provide control over loop bandwidth (LBW) and peaking. As shown in FIG. 6, Vcap (voltage across capacitor C1) in the LF is fed back to the drain nodes M1, M3 in the CP through a unity gain buffer. This maintains the voltage across CP current sources to be relatively constant during the phase detector (PD) switching. The feedback path from the loop filter to the charge pump (e.g., Vcap_cp) facilitates reduction of deterministic jitter. The CP, LF output (Vctl) feeds into the VCO 202 as shown in FIG. 3, e.g., VCO 202-A or 202-B

FIG. 6B illustrates an example circuit diagram illustrating the architecture of an individual charge pump with a third-order loop filter 214-B incorporating a low pass filter (LPF) 215 accordance with an aspect of the subject specification. In particular, all components, C1, C2, and R1, in LF 214-B including the fully programmable components C3 and R2 of LPF 215 to provide a fully programmable third-order filter. Loop filter 214-B can provide mux selectability to either include or bypass the LPF 215 for additional configurability.

FIG. 7 illustrates an example design of a passive loop filter in accordance with an aspect of the present innovation. The loop filter 214 includes an R select 702 and a C2 select 704 that provide the programmability in the loop filter resistors 706 and 708, and ripple capacitors 710 and 712, respectively. The designer can activate one or both of the filter resistors 706 and 708 via the R select 702. For instance, if R select 702 is set to binary zero (0) then the filter resistor 706 is activate, and if R select 702 is set to a binary one (1) then both filter resistors 706 and 708 are active. Therefore, the resistance in the loop filter 214 can be R or can be two times R. Similarly, the designer can activate one or both of the ripple capacitors 710 and 712 via the C2 select 704. Therefore, the capacitance in the loop filter 214 can be C2 or twice C2. The programmability incorporated in the charge pump 208, 600 (discussed previously) and the loop filter 214 enable the loop filter to achieve a LBW range of 1.6 to 9 MHz.

Turning now to FIG. 8, an example detailed circuit diagram illustrating programmable VCO bias current circuit 304 architecture in accordance with an embodiment of the subject innovation is shown. The digital calibration circuit 210 (discussed supra in FIG. 2) selects the VCO bias current for every calibration code so as to maximize output amplitude without pushing the LC tank 214 into the voltage-limited region. This scheme optimizes the VCO 202 phase noise across its frequency range and is made programmable to compensate for future process shifts in either manufacturing, lifespan degradation of a device, or both. Self-bias block 321 of FIG. 3B is implemented as self-bias circuit 821 in the present embodiment having a diode-connected cascode referenced from a current mirror. VCO bias current select block 319 of FIG. 3B is implemented as VCO bias current select circuit 819 in the present embodiment as a power down block, e.g., any type of multiplexer such as an analog mux, with a pull-up disable.

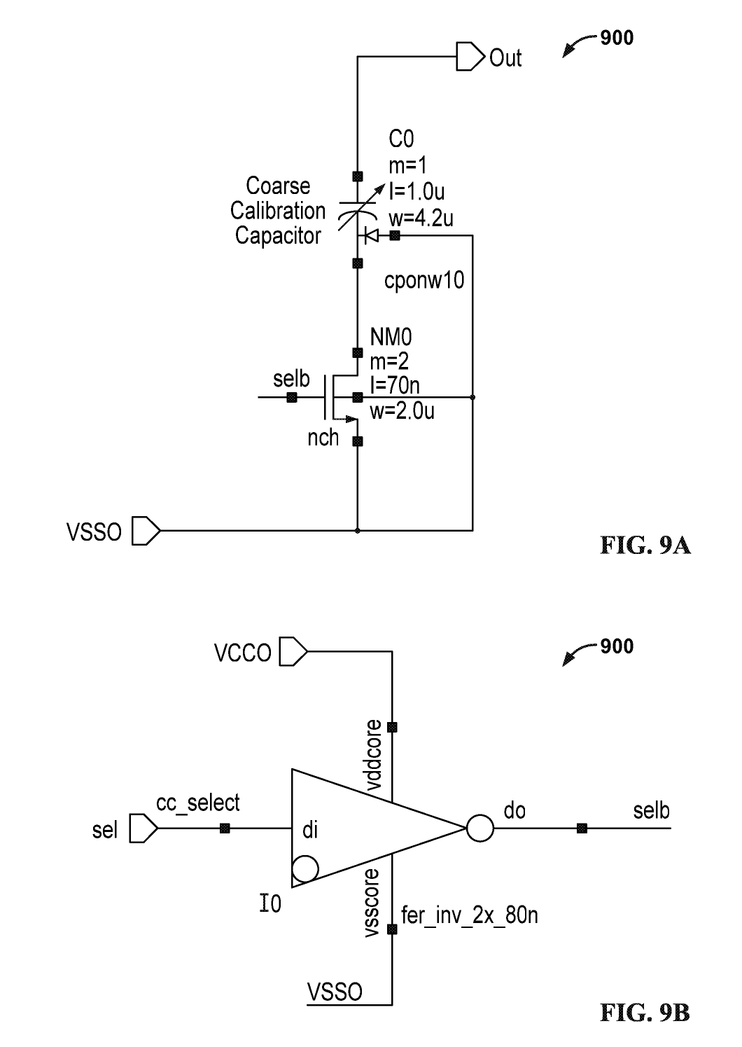

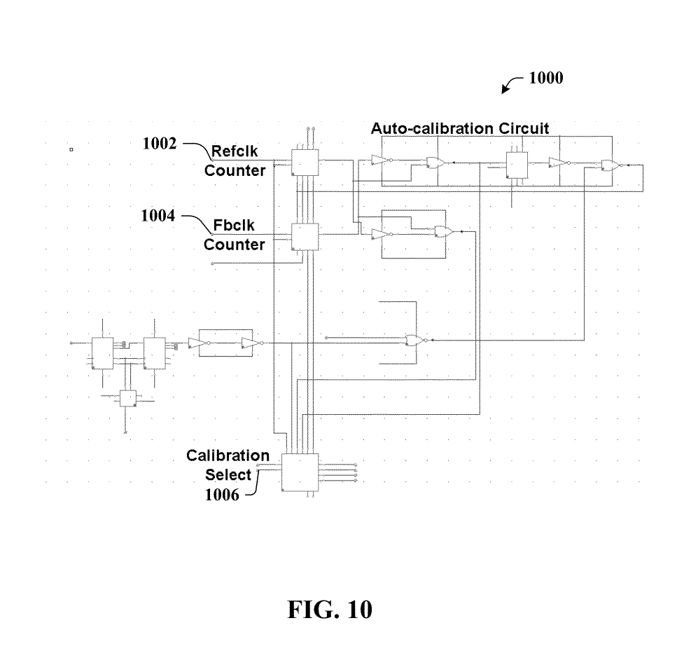

FIG. 9 illustrates an example coarse calibration circuit unit cell 900 in accordance with an aspect of the subject innovation. Each coarse calibration block includes 32 digitally switchable 1.0V NMOS in Nwell accumulation-mode MOS capacitors with NMOS switches controlled by the digital auto-calibration circuit (see FIG. 10). On start-up, all of the coarse calibration capacitors can be selected. The coarse calibration circuit provides the wide coarse tuning range of 2.3 to 4.6 GHz, after which, fine-tuning occurs.

Illustrated in FIG. 10 is an example circuit diagram showing an auto-calibration circuit in accordance with an aspect of the present disclosure. The auto-calibration circuit 1000 includes two counters, one that is clocked by the reference clock 1002 (e.g., refclk counter) and the other by the feedback clock 1004 (e.g., feedback clock counter). The maximum count value on these counters is programmable to 2.sup.8, 2.sup.10, 2.sup.12, or 2.sup.14. If the reference clock counter 1002 reaches the maximum count before the feedback clock counter 1004, the calibration select circuit 1006 de-selects a coarse calibration capacitor from the LC tank and the counter process is restarted. This process repeats until the feedback clock counter 1004 reaches its maximum count before the reference clock counter 1002. Subsequently, fine-tuning occurs. It is to be appreciated FIG. 10 illustrates but a single example, and the auto-calibration circuit could alternatively be implemented in hardware, software, FPGA, and so forth.

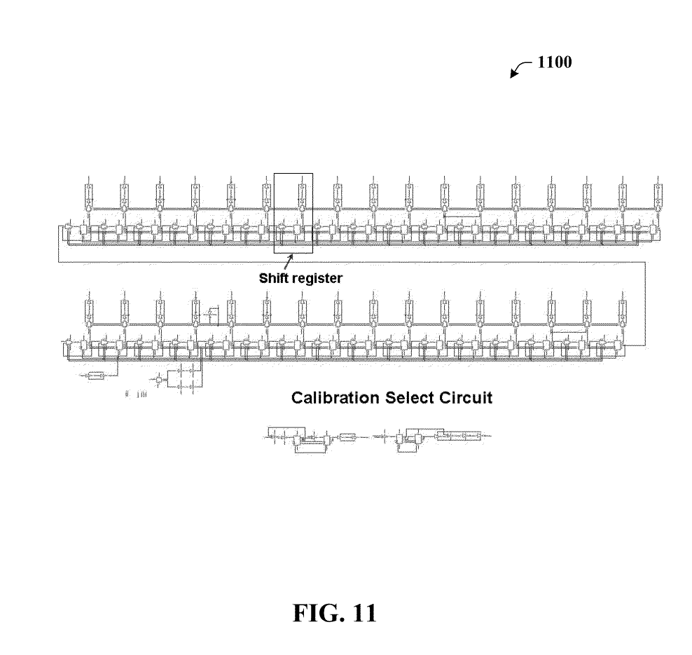

Referring to FIG. 11, an example circuit diagram illustrating a calibration select circuit 1100 is shown in accordance with an aspect of the current innovation. The calibration select circuit 1100 consists of shift registers and control logic that is clocked by the reference clock.

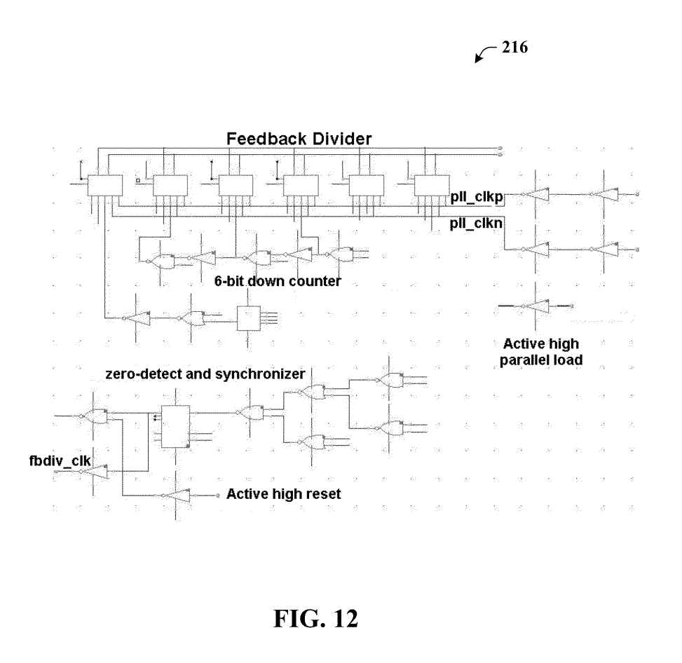

FIG. 12 illustrates an example top-level diagram of a feedback divider 216 in accordance with an aspect of the current innovation. The feedback divider 216 is comprised of completely static CMOS using toggle flops, and designed for low power/high speed operation. In addition, the feedback divider 216 is programmable, and can divide a feedback signal (e.g., VCO output) by N, wherein N is an integer between two (2) and sixty four (64) inclusive.

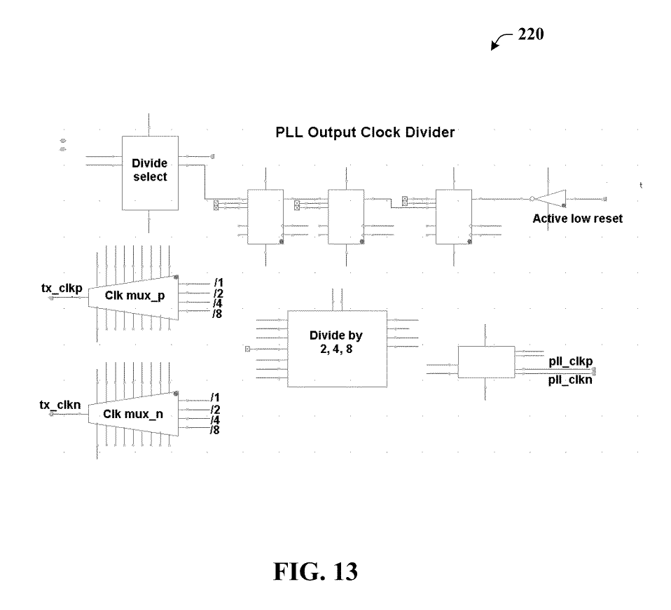

FIG. 13 illustrates an example top-level diagram of a per lane clock divider 220 in accordance with an aspect of the current innovation. The per lane clock divider 220 is a programmable clock divider that can be implemented at the transmission (e.g., Tx) input of each lane to divide the frequency of the output signal of the LC VCO 202 by an Integer M, wherein M can be one (1), two (2), four (4), or eight (8). As discussed previously, the per lane clock divider 220 is controlled by the calibration control block 210. In the preferred embodiment, the clock divider 220 can be programmed to provide a lane with a data transfer rate between 0.586 Gb/s to 10 Gb/s. Specifically, a programmable PLL output clock divide of 8 with PLL locked at 2.343 GHz enables 0.586 Gb/s; output clock divide of I with PLL locked at 5 GHz enables 10 Gb/s. The data transfer rate for each lane can be set independently of the data rates of the other lanes or in relation to the data rates of the other lanes.

### Actual Test Results

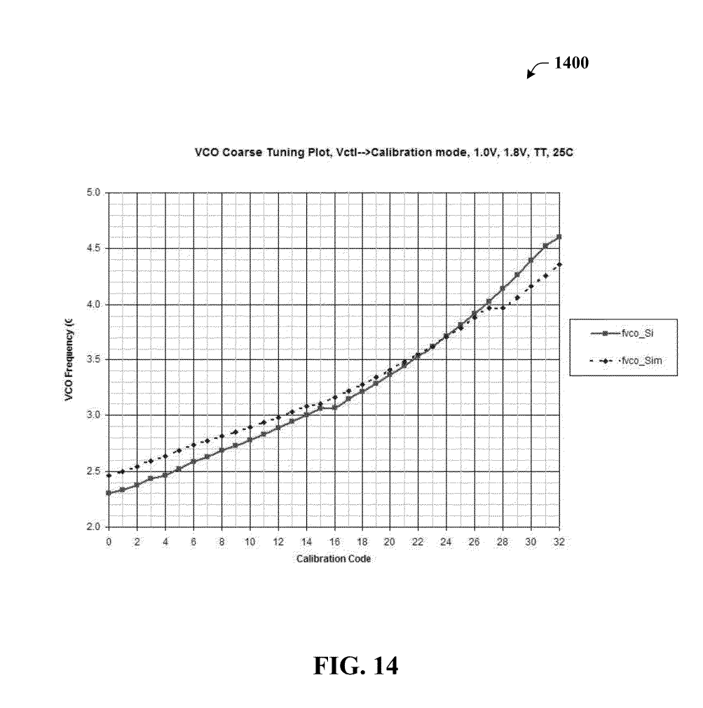

The following FIGS. 14-19 are illustrative of test conducted by the inventors for the innovation described in the preceding figures (e.g., FIGS. 2-13). The test results demonstrate that the innovation operates as asserted herein, and that the innovation has actually been reduced to practice. It is to be appreciated, that these test results are for but one example embodiment, and a plurality of other possible tests and results are possible within the scope and spirit of the subject innovation.

FIG. 14 illustrates a plot 1400 of the open loop VCO output frequency measurement in GHz (Y-axis) versus the calibration code measurements (X-axis) (i.e. number of capacitors selected) for silicon (fvco_Si) and simulation tuned for inline device characteristics and parasitic extraction (fvco_Sim). As can been seen, the silicon measurements closely track the simulation measurements.

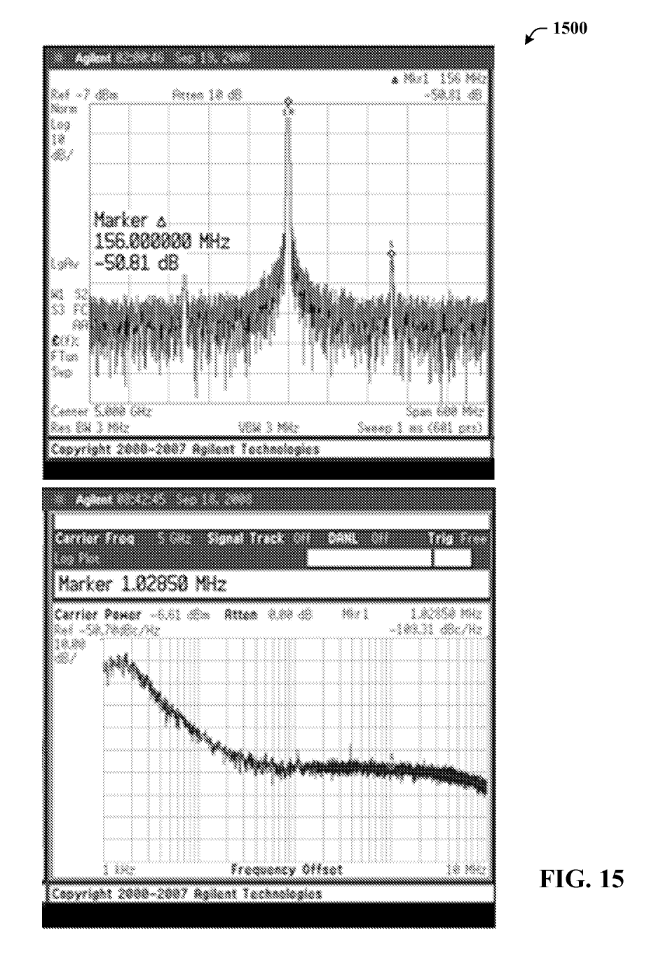

FIG. 15 shows a spectrum analyzer screenshot 1500 illustrating the closed loop frequency spectrum of the PLL locked at 5 GHz (10 Gb/s) with a clock pattern coming out on the TX. Reference spurs are observed at .DELTA.f=.+−0.156 MHz with a relative power of −50.81 dB with regard to the carrier. With the PLL locked at 5 GHz, closed loop phase noise at 1 MHz offset is measured to be −109.31 dBc/Hz. The test was conducted using an Agilent® E4440A 3 Hz-26.5 GHz PSA Series Spectrum Analyzer.

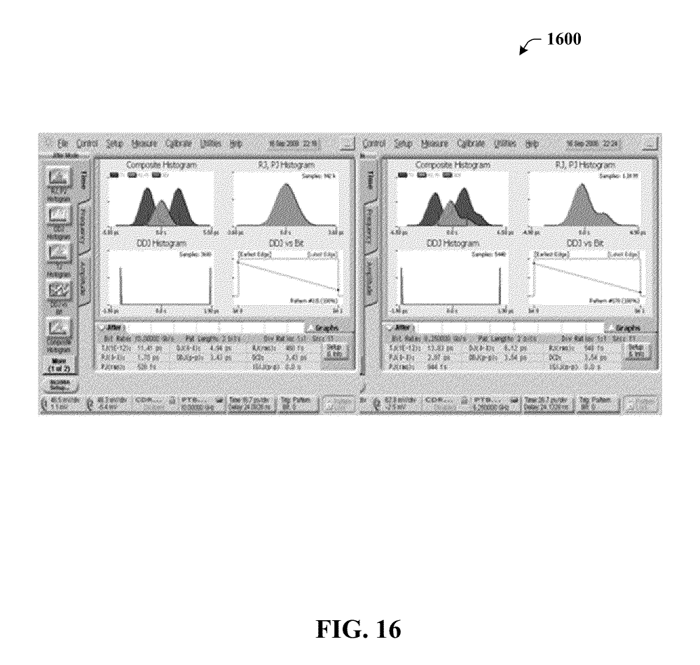

FIG. 16 shows a screenshot 1600 illustrating jitter measurements of a PLL disclosed in accordance with the current innovation. The PLL is shown operating at 5 GHz (10 Gb/s) and 3.125 GHz (6.25 Gb/s), with a clock pattern generated from the transmission line (Tx). The RJ.sub.rms equals 460 fs at 5 GHz, and 548 fs at 3.125 GHz. The clock and data recovery (CDR) is disabled and an external reference clock (e.g., 156.25 MHz) is used as a trigger through the precision time base (PTB) input. The results were obtained via an Agilent® 86100C DCA-J sampling oscilloscope with an Agilent® 86108A precision waveform analyzer module.

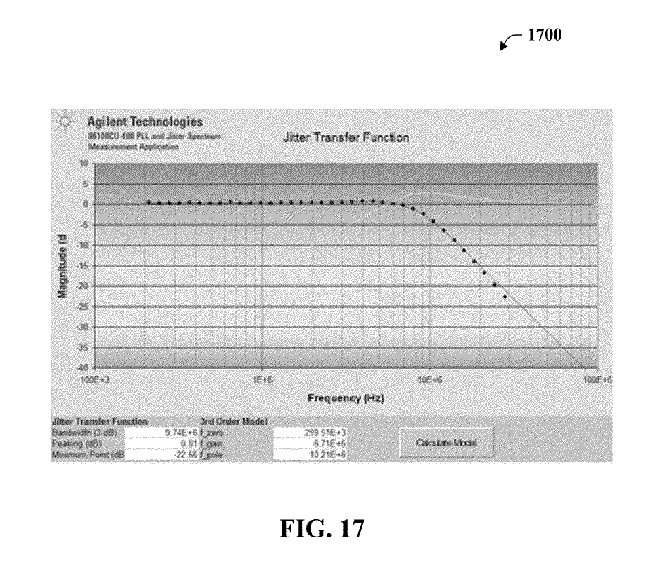

FIG. 17 is a jitter transfer plot 1700 of a phase-locked loop at 3.125 GHz in accordance with an aspect of the current innovation. As shown on the plot, the PLL loop bandwidth (LBW) at maximum setting was measured to be 9.74 MHz with 0.81 dB of peaking. The test was performed using an Agilent 86100C DCA-J sampling oscilloscope with 86108A precision waveform analyzer module, and an Agilent® 86100CU-400 PLL and jitter spectrum measurement application.

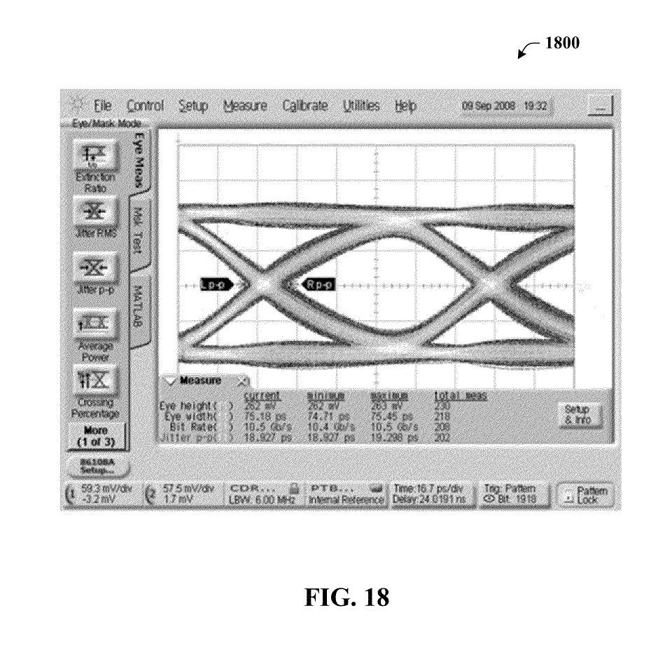

FIG. 18 is a screenshot 1800 illustrating a transmission (Tx) eye at 10 Gb/s with a PRBS11 pattern. PRBS11 refers to Pseudo Random Binary Sequence with a length of 2047 bits. The clock and data recovery (CDR) loop bandwidth (LBW) is set to 6 MHz (rate/1667) and precision time base (PTB) is enabled. The horizontal axis represents time and the vertical axis represents the Tx signal voltage. The Tx eye consists of a maximum Tx signal voltage of 262 mV and has a duration of 74.71 ps. The screenshot was captured from an Agilent® 86100C DCA-J sampling oscilloscope with an Agilent® 86108A precision waveform analyzer module.

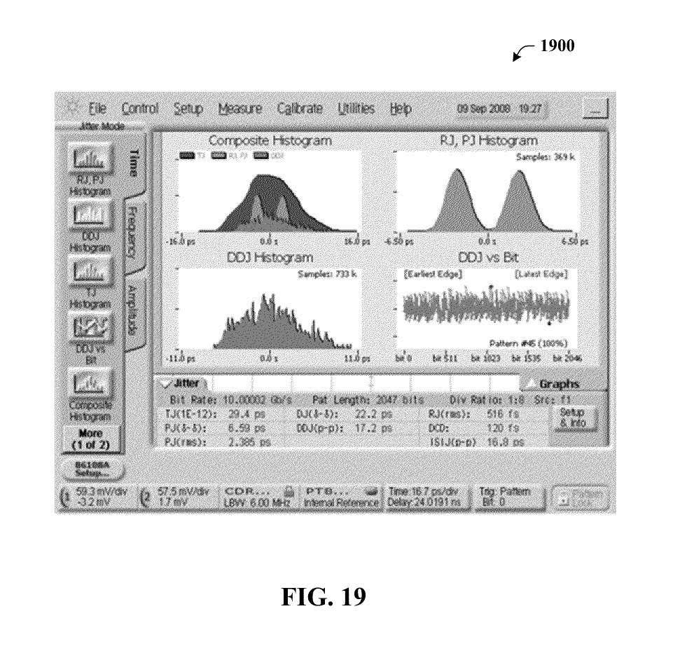

FIG. 19 is a screenshot 1900 illustrating transmission (Tx) jitter at 10 Gb/s with a PRBS11 pattern. The clock and data recovery (CDR) loop bandwidth (LBW) was set to 6 MHz (rate/1667), and the precision time base (PTB) was enabled. The RJ.sub.rms was measure to be 516 fs at 10 Gb/s. The results were obtained using an Agilent® 86100C DCA-J sampling oscilloscope with an Agilent® 86108A precision waveform analyzer module.

While the present disclosure focuses on one application of the low-noise bias circuit in an LC VCO based PLL, the apparatus and methodology of the present disclosure is well-suited to a wide range of PLLs, such as a coupled oscillator PLL, a digitally controlled oscillator (DCO) PLL, a ring oscillator PLL, and other PLL circuits that can benefit from a low-noise bias current. Furthermore, the low-noise bias circuit is useful in other applications that can benefit from a low-noise bias current.

Methods and operations described herein can be in different sequences than the exemplary ones described herein, e.g., in a different order. Thus, one or more additional new operations may be inserted within the existing operations or one or more operations may be abbreviated or eliminated, according to a given application, so long as substantially the same function, way and result is obtained.

While the foregoing disclosure discusses illustrative aspects and/or embodiments, it should be noted that various changes and modifications could be made herein without departing from the scope of the described aspects and/or embodiments as defined by the appended claims. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

I/We claim:

1. A phase-locked loop circuit comprising:
a charge pump coupled to receive an error signal that is proportional to a phase difference between a reference clock and a feedback clock, wherein the charge pump generates an output signal in response to the error signal, wherein the charge pump comprises a capacitor;
a loop filter that removes high frequency components above a predetermined threshold from the output signal, thereby creating a voltage control signal;
a feedback loop that provides a feedback voltage from the loop filter to the charge pump, wherein the feedback voltage reduces jitter in the phase-locked loop circuit;
a voltage controlled oscillator that generates a clock signal having a frequency based on the voltage control signal, wherein the voltage controlled oscillator comprises an LC tank circuit;
a VCO regulator that provides a regulated voltage; and
a bias circuit that supplies a bias current to the LC tank circuit, wherein the bias circuit comprises:
a plurality of transistors cascode-coupled to each other and disposed in between the VCO regulator and the LC tank circuit.

2. The circuit of claim 1, wherein the plurality of transistors comprises a single pair of PMOS transistors that are cascode-coupled to each other.

3. The circuit of claim 1, wherein the plurality of transistors are grouped into multiple branches of cascode-coupled transistor pairs, wherein each of the multiple branches is coupled in parallel to each other and disposed between the VCO regulator and the LC tank circuit.

4. The circuit of claim 3, further comprising:
means for controlling the plurality of transistors in response to a calibration code.

5. The circuit of claim 1 further comprising:
an auto-calibration component that generates a calibration code in response to the reference clock signal and the feedback clock signal, wherein the calibration code activates a set of calibration capacitors in the LC tank circuit; and
wherein the bias circuit adjusts the bias current in response to the calibration code.

6. The circuit of claim 1 wherein the loop filter is a third-order loop filter.

7. The circuit of claim 1 wherein:
the loop filter comprises:
an adjustable capacitor coupled between an output of the charge pump and a voltage supply terminal;
an adjustable resistor coupled between the output of the charge pump and a first node; and
a fixed capacitor coupled between the first node and the voltage supply terminal; and
the feedback loop comprises:
a buffer having an input coupled to the first node and an output coupled to the capacitor of the charge pump; and
wherein the feedback voltage reduces jitter in the phase-locked loop circuit.

8. A phase-locked loop circuit comprising:
a voltage controlled oscillator that generates a feedback clock signal in response to a reference clock signal, wherein the voltage controlled oscillator includes an LC tank circuit having a plurality of calibration capacitors;
an auto-calibration circuit that compares the feedback clock signal and the reference clock signal, and in response, generates a calibration code that activates a set of the calibration capacitors to allow the PLL to lock to a desired frequency;
a VCO regulator, which provides a regulated supply voltage; and
a plurality of transistors cascode-coupled to each other and disposed between the VCO regulator and the LC tank circuit.

9. The circuit of claim 8, wherein the plurality of transistors are PMOS transistors.

10. The circuit of claim 8, wherein the plurality of transistors are coupled into a plurality of parallel branches each having a cascode-coupled pair of transistors.

11. The circuit of claim 10, wherein the plurality of parallel branches is controlled in response to the calibration code, thereby selecting a bias current for the LC tank circuit.

12. The circuit of claim 10 wherein any combination of the plurality of parallel branches can be selectively enabled to provide a range of currents to the voltage controlled oscillator.

13. A phase-locked loop circuit, comprising:
a voltage controlled oscillator that generates a feedback clock signal in response to a reference clock signal, wherein the voltage controlled oscillator includes an LC tank circuit having a plurality of calibration capacitors;
a plurality of noise-reducing stages coupled in series and disposed between an external power supply and the voltage controlled oscillator in order to provide a low-noise current source to the voltage controlled oscillator.

14. The circuit of claim 13 wherein the plurality of noise-reducing stages comprises:
a VCO regulator that provides a regulated voltage; and
a bias circuit that supplies a bias current to the LC tank circuit.

15. The circuit of claim 14, wherein the bias circuit comprises:
a plurality of transistors cascode-coupled to each other and disposed between the VCO regulator and the LC tank circuit.

16. The circuit of claim 15, wherein the plurality of transistors comprise PMOS transistors.

17. The circuit of claim 13, wherein the plurality of transistors are grouped one or more branches of cascode-coupled transistor pairs, wherein each of the one or more branches is coupled in parallel to each other and disposed between the VCO regulator and the LC tank circuit.

18. The circuit of claim 17, wherein any combination of the one or more branches can be selectively enabled to provide a range of currents to the voltage controlled oscillator.

19. A method of auto-calibrating a phase-locked loop, comprising:
generating a feedback clock signal in response to a reference clock signal using an LC tank circuit having a plurality of calibration capacitors;
comparing the feedback clock signal and the reference clock signal, and in response, generating a calibration code that activates a set of the calibration capacitors to lock the PLL;
generating a regulated supply voltage, which is provided on a VCO regulator terminal; and
filtering residual noise from the VCO regulator via a plurality of transistors cascode-coupled to each other in a bias circuit that is disposed between the VCO regulator terminal and the LC tank circuit.

20. The method of claim 19 further comprising:
enabling one or more sets of parallely arranged cascode-coupled transistor pairs in response to the configuration code, thereby selecting a bias current for the LC tank circuit.

21. The method of claim 20, wherein the operation of generating the calibration code comprises:
initially activating all calibration capacitors in the LC tank circuit;
comparing the reference clock signal with the feedback clock signal; and
de-activating one or more calibration capacitors of the LC tank circuit if the reference clock signal has a higher frequency than the feedback clock signal.

22. The method of claim 21 further comprising:
decreasing the bias current when one of the calibration capacitors is de-activated.

23. The method of claim 20 further comprising:
selecting the bias current to maximize an amplitude of an output signal provided by the LC tank circuit, without causing the LC tank circuit to operate in a voltage-limited region.

24. The method of claim 20 wherein the operation of generating the calibration code occurs at approximately the same time to configure both the calibration capacitors and the cascode-coupled transistors in the bias circuit.

25. A method of reducing noise in a current source for a phase-locked loop, comprising:
generating a feedback clock signal in response to a reference clock signal using an LC tank circuit having a plurality of calibration capacitors;
comparing the feedback clock signal and the reference clock signal to lock the PLL, and in response, generating a calibration code that activates a set of the calibration capacitors;
generating a regulated supply voltage, this is provided on a VCO regulator terminal;
removing residual noise from the VCO regulator via a plurality of transistors cascode-coupled to each other and disposed between the VCO regulator terminal and the LC tank circuit; and
supplying a low-noise bias current to the LC tank circuit.

26. The method of claim 25 further comprising:
selectively enabling one or more sets of parallely arranged cascode-coupled transistors to generate the bias current for the LC tank circuit.

27. The method of claim 26 further comprising:
generating a calibration code to automatically select the one or more sets of parallely arranged cascode-coupled transistors based on the reference clock signal.

28. The method of claim 27 wherein the operation of generating is performed in response to inputs from the reference clock signal and the feedback clock signal.
